(19) United States
(12) Patent Application Publication
(10) Pub. No.: US 2025/0331267 A1
(43) Pub. Date: Oct. 23, 2025

(54) SELF-LIMITED ETCHING OF LOW-K MATERIALS

(71) Applicant: Applied Materials, Inc., Santa Clara, CA (US)

(72) Inventors: Lala Zhu, Fremont, CA (US); Zihui Li, Santa Clara, CA (US); Anchuan Wang, San Jose, CA (US); Nitin K. Ingle, San Jose, CA (US)

(73) Assignee: Applied Materials, Inc., Santa Clara, CA (US)

(21) Appl. No.: 18/643,100

(22) Filed: Apr. 23, 2024

(51) Int. Cl. H01L 29/66; H01L 21/02; H01L 21/311; H01L 29/06; H01L 29/423

(52) U.S. Cl. CPC H10D 64/015; H01L 21/02167; H01L 21/0217; H01L 21/31116; H10D 30/6735; H10D 62/121; H10D 64/018

(57) ABSTRACT

Exemplary semiconductor processing methods may include providing a hydrogen-containing precursor and a nitrogen-containing precursor to a processing region of a semiconductor processing chamber. A substrate may be disposed within the processing region. The substrate may include a layer of a silicon-containing material. The methods may include forming plasma effluents of the hydrogen-containing precursor and the nitrogen-containing precursor. The methods may include contacting the substrate with plasma effluents of the hydrogen-containing precursor and the nitrogen-containing precursor. The contacting may reduce a carbon concentration, a nitrogen concentration, or both in a portion of the layer of the silicon-containing material. The methods may include providing one or more etchant precursors to the processing region. The methods may include contacting the substrate with the one or more etchant precursors. The contacting may remove the portion of the layer of the silicon-containing material.

### TECHNICAL FIELD

The present technology relates to semiconductor processes and equipment. More specifically, the present technology relates to self-limited etching low-k materials, such as silicon-containing materials.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a hydrogen-containing precursor and a nitrogen-containing precursor to a processing region of a semiconductor processing chamber. A substrate may be disposed within the processing region. The substrate may include a layer of a silicon-containing material. The methods may include forming plasma effluents of the hydrogen-containing precursor and the nitrogen-containing precursor. The methods may include contacting the substrate with plasma effluents of the hydrogen-containing precursor and the nitrogen-containing precursor. The contacting may reduce a carbon concentration, a nitrogen concentration, or both in a portion of the layer of the silicon-containing material. The methods may include providing one or more etchant precursors to the processing region. The methods may include contacting the substrate with the one or more etchant precursors. The contacting may remove the portion of the layer of the silicon-containing material.

In some embodiments, the hydrogen-containing precursor may be or include diatomic hydrogen (H₂). The nitrogen-containing precursor may be or include diatomic nitrogen (N₂). The silicon-containing material may further include carbon, nitrogen, or both. The portion of the layer of the silicon-containing material may be characterized by a thickness of greater than or about 5 Å. The portion of the layer of the silicon-containing material may be characterized by a thickness of less than or about 25 Å. The processing region may be maintained plasma-free while contacting the substrate with the one or more etchant precursors. The methods may include repeating the operations for a plurality of cycles to remove the layer of the silicon-containing material. A temperature within the processing region may be maintained at less than or about 500° C. A pressure within the processing region may be maintained between about 1 Torr and about 10 Torr. The layer of the silicon-containing material may be an inner spacer of a gate all around (GAA) structure.

Some embodiments of the present technology may encompass semiconductor processing methods. The methods may include treating a layer of a silicon-containing material on a substrate is disposed within a processing region of a semiconductor processing chamber. The treating may remove carbon, nitrogen, or both from the layer of the silicon-containing material. The methods may include providing one or more etchant precursors to the processing region. The methods may include contacting the substrate with the one or more etchant precursors. The contacting may remove a portion of the layer of the silicon-containing material.

In some embodiments, treating the layer of the silicon-containing material may include contacting the layer of the silicon-containing material with plasma effluents of a hydrogen-containing precursor and a nitrogen-containing precursor. The plasma effluents of the hydrogen-containing precursor and the nitrogen-containing precursor may be formed at a plasma power of greater than or about 1,000 W. The one or more etchant precursors may be or include one or more fluorine-containing precursors. The one or more fluorine-containing precursors may be or include hydrogen fluoride (HF), nitrogen trifluoride (NF₃), or both. The layer of the silicon-containing material may be treated for a period of time greater than or about 5 seconds. The substrate may further include a second silicon-containing material. The contacting of the substrate with the one or more etchant precursors may selectively remove the portion of the layer of the silicon-containing material relative to the second silicon-containing material.

Some embodiments of the present technology may encompass semiconductor processing methods. The methods may include providing a hydrogen-containing precursor and a nitrogen-containing precursor to a processing region of a semiconductor processing chamber. A substrate may be disposed within the processing region. The substrate may include a layer of a silicon-containing material. The methods may include forming plasma effluents of the hydrogen-containing precursor and the nitrogen-containing precursor. The methods may include contacting the substrate with plasma effluents of the hydrogen-containing precursor and the nitrogen-containing precursor. The contacting may reduce a carbon concentration, a nitrogen concentration, or both in a portion of the layer of the silicon-containing material. The methods may include halting a flow of the hydrogen-containing precursor and the nitrogen-containing precursor. The methods may include providing one or more fluorine-containing precursors to the processing region. The methods may include contacting the substrate with the one or more fluorine-containing precursors. The contacting may remove the portion of the layer of the silicon-containing material. The processing region may be maintained plasma-free while contacting the substrate with the one or more fluorine-containing precursors.

In some embodiments, the methods may include repeating the operations for a plurality of cycles to remove the layer of the silicon-containing material.

Such technology may provide numerous benefits over conventional systems and techniques. For example, the processes may selectively etch one silicon-containing material relative to other silicon-containing materials. Additionally, the etching may reduce damage to other materials as well as reduce contamination, both of which may impact subsequent operations and final device performance. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

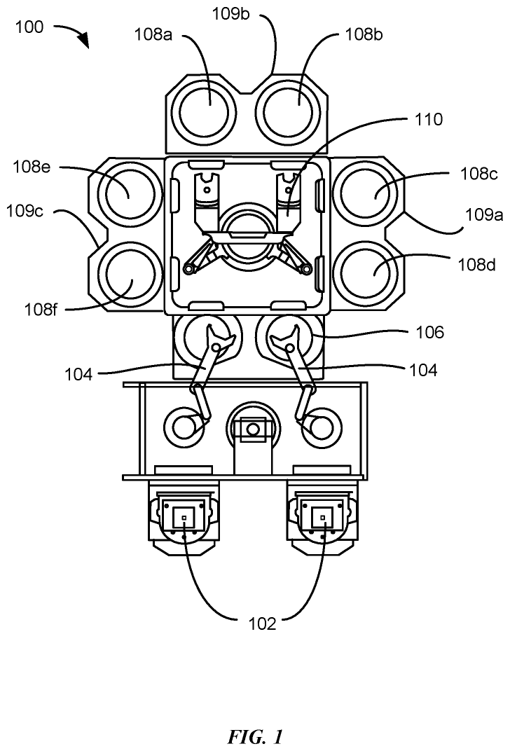

FIG. 1 shows a top plan view of one embodiment of an exemplary processing system according to embodiments of the present technology.

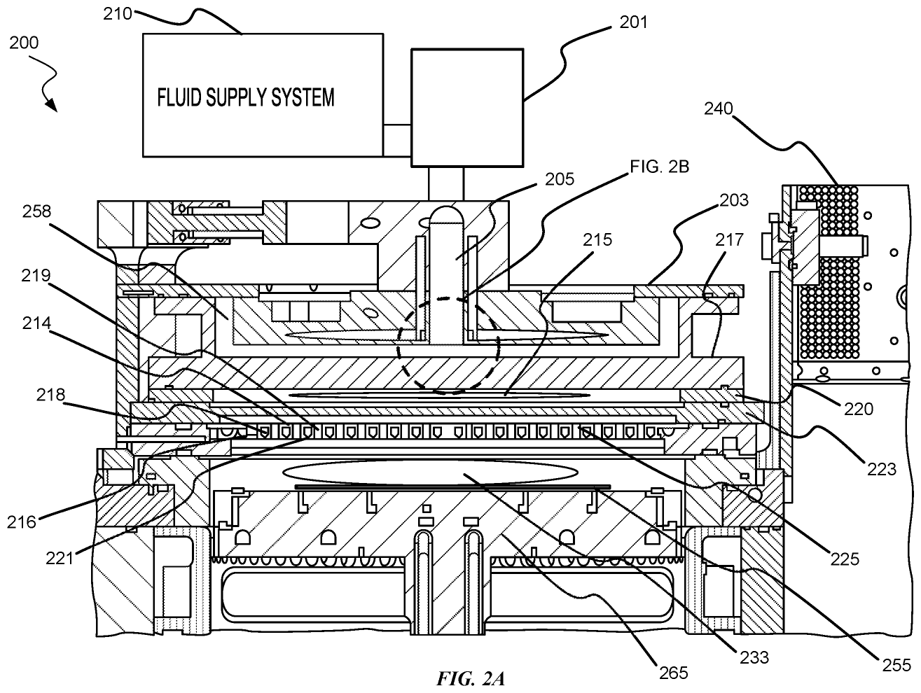

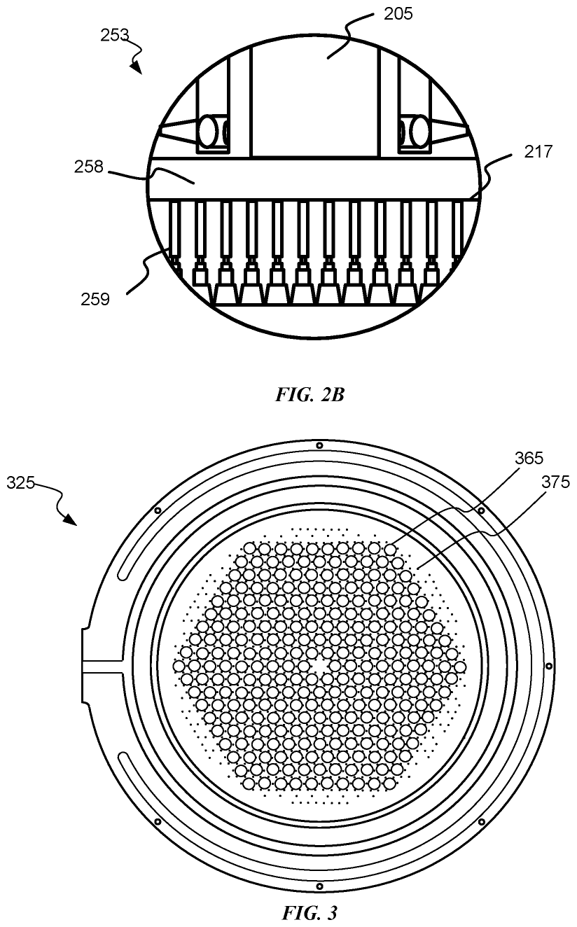

FIG. 2A shows a schematic cross-sectional view of an exemplary processing chamber according to embodiments of the present technology.

FIG. 2B shows a detailed view of a portion of the processing chamber illustrated in FIG. 2A according to embodiments of the present technology.

FIG. 3 shows a bottom plan view of an exemplary showerhead according to embodiments of the present technology.

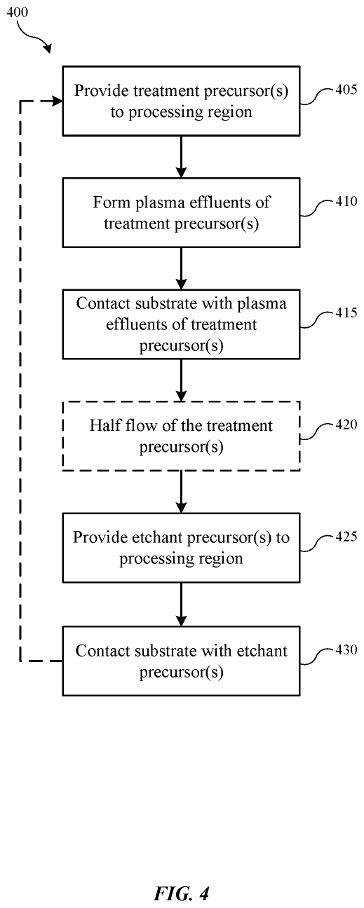

FIG. 4 shows exemplary operations in a method according to embodiments of the present technology.

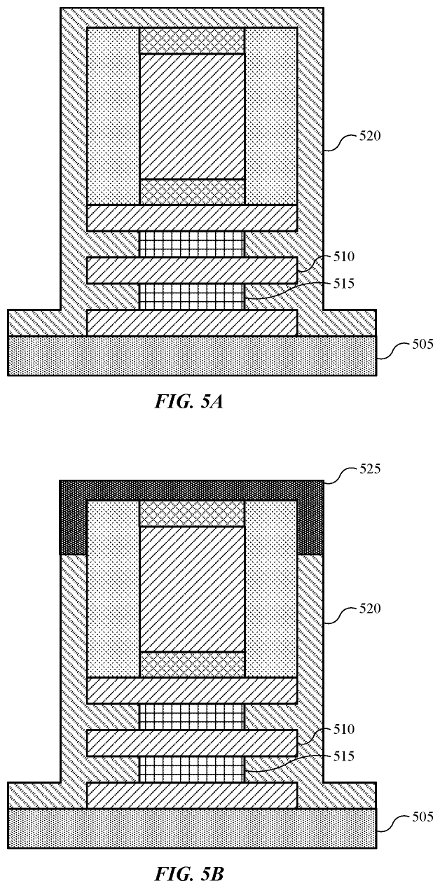

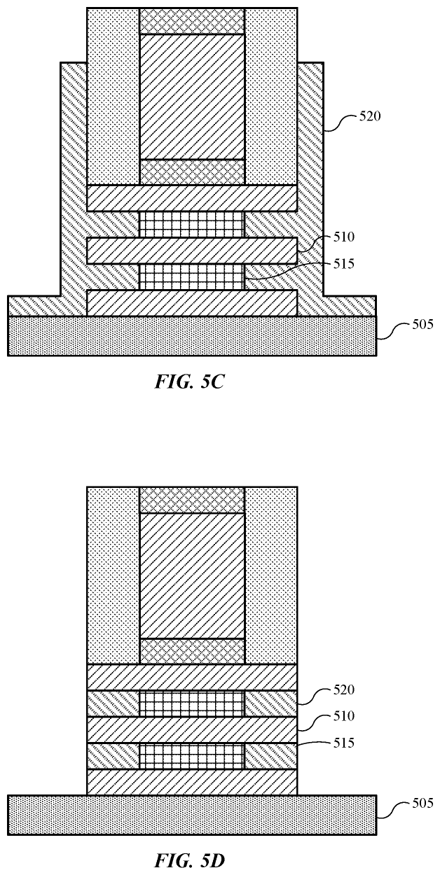

FIGS. 5A-5D show cross-sectional views of substrates being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning to gate-all-around (GAA) transistors, many process operations are modified from more conventional fin field-effect (FinFET) transistors. Additionally, as structures continue to reduce in size, the thicknesses of material layers reduce and the aspect ratios of memory holes and other structures increase, sometimes dramatically.

During GAA processing, alternating layers of material are deposited on a substrate, such as alternating layers of silicon-containing material and silicon-and-germanium-containing material. In forming the transistor, memory holes or trenches may be formed through the alternating layers of material. During GAA processing, the silicon-and-germanium-containing material may be recessed from within the memory holes or trenches to form material that will serve as nanowires/nanosheets. An inner spacer may be deposited in the formed recesses.

The inner spacer may be deposited over the structure and a subsequent removal process may remove inner spacer material outside the formed recesses. Conventional technologies may use a reactive ion etching (RIE) process. However, RIE may damage other materials present on the substrate, such as a shallow trench isolation (STI) material. Additionally, inner spacer materials may include carbon and/or nitrogen. The RIE may leave carbon and/or nitrogen residue on the substrate that may impact growth of epitaxial material in subsequent operations. The damage to other materials present on the substrate or presence of residue may impact performance of final devices. For example, damage STI material or impacted epitaxial material may degrade electrical performance of GAA structures.

The present technology overcomes these issues by performing a treatment prior to etching silicon-containing material. The treatment may include forming plasma effluents of a treatment precursor and contacting the substrate with the treatment precursor. The treatment precursor and plasma effluents thereof, if formed, may remove carbon and/or nitrogen from the silicon-containing material. By removing carbon and/or nitrogen from the silicon-containing material, the subsequent etch may selectively remove the treated portion of the silicon-containing material (i.e., the silicon-containing material with reduced carbon and/or nitrogen). The treatment may be self-limiting, such that only a certain thickness or portion of the silicon-containing material may be treated. Since the subsequent etch may selectively remove the treated portion of the silicon-containing material, the etch may also be self-limiting based on the previous treatment. Thus, the present technology may iteratively etch through a silicon-containing material with reduced damage to other materials on the substrate as well as reduced carbon and/or nitrogen contamination. Accordingly, the present technology may result improved device performance of GAA structures.

Although the remaining disclosure will routinely identify specific treatment etching processes utilizing the disclosed technology, it will be readily understood that the systems and methods are equally applicable to etching processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the operations described.

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiGeₓ:SiOₓ etch ratios, SiGeₓ:Si etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which materials may be etched increase. Accordingly, an exposed region of material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

The chambers discussed previously may be used in performing exemplary semiconductor processing methods including etching methods. Turning to FIG. 4 is shown exemplary operations in a method 400 according to embodiments of the present technology. Prior to the first operation of the method a substrate may be processed in one or more ways before being disposed within a processing region of a chamber in which method 400 may be performed. For example, alternating layers of material may be formed on the substrate and then one or more memory holes or trenches may be formed through the alternating layers. The alternating layers may include any number of materials, and may include alternating layers of a silicon-containing material and a silicon-and-germanium-containing material. Although the disclosure references silicon-containing material and silicon-and-germanium-containing material, any other known materials used in these two layers may be substituted for one or more of the layers. After additional processing, such as gate all around (GAA) processing, an inner spacer may be formed in the memory holes or trenches. Method 400 may be performed to trim or remove a portion of the inner spacer. Some or all of these operations may be performed in chambers or system tools as previously described, or may be performed in different chambers on the same system tool, which may include the chamber in which the operations of method 400 are performed.

The method 400 may include providing one or more treatment precursors, such as a pre-treatment precursor(s) or pre-etching precursor(s), to a remote plasma region or a processing region of a semiconductor processing chamber at operation 405. In some embodiments, an inert precursor may be provided with the treatment precursor(s). An exemplary chamber may be chamber 200 previously described, which may include the RPS unit 201, first plasma region 215, or processing region 233. Plasma effluents of the treatment precursor(s) may be formed within the remote plasma region or the processing region at operation 410. If formed remotely, the plasma effluents may be flowed to the processing region of the chamber. The plasma effluents may contact the substrate in the processing region at operation 415, which may include a layer of a silicon-containing material, such as silicon-and-oxygen-containing material. The silicon-containing material may further include carbon, nitrogen, or both among other constituents that may be present. The contact between the plasma effluents of the treatment precursor(s) and the substrate may reduce a carbon concentration, a nitrogen concentration, or both in a portion of the layer of the silicon-containing material. In embodiments where the silicon-containing material is mostly silicon and oxygen with carbon and/or nitrogen, the contact between the plasma effluents of the treatment precursor(s) and the substrate may reduce or remove the carbon and/or nitrogen in the portion of the layer of the silicon-containing material to leave a silicon-and-oxygen-containing material. Conventional methods for etching silicon-containing material, such as silicon-and-oxygen-containing material, may then be performed to remove the portion of the layer of the silicon-containing material. As such, method 400 may include halting a flow of the one or more treatment precursors at optional operation 420 followed by providing one or more fluorine-containing precursors to the processing region at operation 425. At operation 430, method 400 may include contacting the substrate with the one or more etchant precursors. The contacting may remove the portion of the layer of the silicon-containing material. The reduction in carbon and/or nitrogen in the layer of the silicon-containing material may be limited to a certain depth. Accordingly, the removal of the portion of the layer of the silicon-containing material may be self-limited based on the depth of the portion of the layer of the silicon-containing material affected by the treatment.

Precursors provided at operation 405 may be or include a hydrogen-containing precursor and/or a nitrogen-containing precursor, which may be flowed into the processing region or the remote plasma region, which may be separate from, but fluidly coupled with, the processing region. The hydrogen-containing precursor may be or include, for example, diatomic hydrogen (H₂), steam (H₂O), hydrogen peroxide (H₂O₂), ammonia (NH₃), or any other hydrogen-containing precursor used or useful in semiconductor processing. The nitrogen-containing precursor may be or include, for example, diatomic nitrogen (N₂), nitrous oxide (N₂O), ammonia (NH₃), or any other nitrogen-containing precursor used or useful in semiconductor processing. Some treatment precursors provided at operation 405 may include both hydrogen and nitrogen, such as NH₃. In embodiments, the treatment precursor(s) may be provided with an inert precursor. The inert precursor may be or include, for example, argon, helium, xenon, or other noble, inert, or useful precursors. The inert precursor may be used to dilute the treatment precursor(s) or may assist in distributing the treatment precursor(s) throughout the processing region.

A flow rate of the treatment precursor(s) may be sufficient to treat the substrate, such as the silicon-containing material, prior to performing etching operations. In embodiments, a flow rate of the treatment precursor(s) to the processing region or the remote plasma system may be greater than or about 1 sccm, and may be greater than or about 5 sccm, greater than or about 10 sccm, greater than or about 15 sccm, greater than or about 20 sccm, greater than or about 25 sccm, greater than or about 30 sccm, greater than or about 35 sccm, greater than or about 40 sccm, greater than or about 45 sccm, greater than or about 50 sccm, greater than or about 60 sccm, greater than or about 75 sccm, greater than or about 100, or higher. These flow rates may apply to each of the treatment precursors provided or a total flow rate of all of the treatment precursors.

In embodiments, plasma effluents of the treatment precursor(s) may be generated at operation 410. However, it is contemplated that plasma effluents may not be formed of the treatment precursor(s) and a plasma-free or thermal treatment may be performed. As discussed, the plasma effluents may be generated in the processing region or in the remote plasma system. In embodiments, the plasma effluents of the treatment precursor(s) may be generated at a plasma power of less than or about 5,000 W, and may be generated at less than or about 4,750 W, less than or about 4,500 W, less than or about 4,250 W, less than or about 4,000 W, less than or about 3,750 W, less than or about 3,500 W, less than or about 3,250 W, less than or about 3,000 W, less than or about 2,750 W, less than or about 2,500 W, less than or about 2,250 W, less than or about 2,000 W, less than or about 1,750 W, less than or about 1,500 W, less than or about 1,250 W, less than or about 1,000 W, or less. By generating plasma effluents of the treatment precursor(s) at a reduced plasma power, bombardment and damage to the substrate and materials deposited thereon may be limited. However, too little of a plasma power may not dissociate the treatment precursor(s) as desired and may limit the impact of the treatment operation. As such, the plasma effluents of the treatment precursor(s) may be generated at a plasma power of greater than or about 250 W, and may be generated at greater than or about 500 W, greater than or about 750 W, greater than or about 1,000 W, greater than or about 1,250 W, greater than or about 1,500 W, greater than or about 1,750 W, greater than or about 2,000 W, greater than or about 2,500 W, or more.

Method 400 may include contacting the substrate with the treatment precursor(s) at operation 415. The contacting may continue for a sufficient period of time to treat a portion of the silicon-containing material, such as an upper portion or an exposed portion. In embodiments, the period of time may be greater than or about 1 second, and may be greater than or about 2 seconds, greater than or about 3 seconds, greater than or about 4 seconds, greater than or about 5 seconds, greater than or about 6 seconds, greater than or about 7 seconds, greater than or about 8 seconds, greater than or about 9 seconds, greater than or about 10 seconds, greater than or about 15 seconds, greater than or about 20 seconds, or more. However, the treatment may be self-limiting as the treatment precursors may only be able to treat a certain thickness of the silicon-containing material. As such, increased periods of time may not treat an increased portion of the silicon-containing material. Accordingly, the period of time may be less than or about 5 minutes, less than or about 3 minutes, less than or about 2 minutes, less than or about 1 minute, less than or about 50 seconds, less than or about 40 seconds, less than or about 30 seconds, less than or about 20 seconds, less than or about 10 seconds, or less.

By contacting the substrate with the treatment precursor(s), a carbon concentration, a nitrogen concentration, or both in the portion of the layer of the silicon-containing material may be reduced. For example, plasma effluents of the treatment precursor(s), such as plasma effluents of hydrogen and/or nitrogen, may interact with carbon, nitrogen, or both in the portion of the layer of the silicon-containing material and may outgas carbon, nitrogen, or both from the layer. As such, the portion of the silicon-containing material affected by the treatment may have a reduced carbon concentration, nitrogen concentration, or both. For example, if the silicon-containing material further includes carbon and/or nitrogen, the treatment may convert the portion of the silicon-containing material so a silicon-and-oxygen material with a reduced amount of carbon and/or nitrogen.

As previously discussed, the treatment may be self-limiting as the treatment precursors may only be able to treat a certain thickness of the silicon-containing material. In embodiments, the portion of the layer of the silicon-containing material may be characterized by a thickness of greater than or about 5 Å, and may be characterized by a thickness of greater than or about 5.5 Å, greater than or about 6 Å, greater than or about 6.5 Å, greater than or about 7 Å, greater than or about 7.5 Å, greater than or about 8 Å, greater than or about 8.5 Å, greater than or about 9 Å, greater than or about 9.5 Å, greater than or about 10 Å, or more. While processing conditions may be adjusted to increase the thickness of the portion of the layer of the silicon-containing material, since the treatment may be self-limiting, the portion of the layer of the silicon-containing material may be characterized by a thickness of less than or about 25 Å, and may be characterized by a thickness of less than or about 20 Å, less than or about 18 Å, less than or about 16 Å, less than or about 14 Å, less than or about 12 Å, less than or about 10 Å, or less.

As previously discussed, method 400 may include halting a flow of the treatment precursors, such as the hydrogen-containing precursor and/or the nitrogen-containing precursor, at optional operation 420 prior to providing the etchant precursor(s). The etchant precursor(s) provided at operation 425 may include materials able to etch silicon-containing materials. For example, the etchant precursor(s) may be or include halogen-containing precursors. Exemplary halogen-containing precursors may include diatomic fluorine (F₂), hydrogen fluoride (HF), nitrogen trifluoride (NF₃), sulfur hexafluoride (SF₆), carbon tetrafluoride (CF₄), diatomic chlorine (Cl₂), carbon tetrachloride (CCl₄), hydrogen bromide (HBr), or any other halogen-containing precursor used or useful in semiconductor processing. In embodiments, additional precursors may be provided with the etchant precursor, such as hydrogen-containing precursors or nitrogen-containing precursors. For example, NH₃ may be provided with the etchant precursor(s). Further, the etchant precursor(s) may be provided with an inert precursor. The inert precursor may be or include, for example, argon, helium, xenon, or other noble, inert, or useful precursors. The inert precursor may be used to dilute the etchant precursor(s) or may assist in distributing the etchant precursor(s) throughout the processing region.

A flow rate of the etchant precursor(s) may be sufficient to etch the layer of the silicon-containing material, such as the portion of the silicon-containing material treated at operation 415. In embodiments, a flow rate of the etchant precursor(s) to the processing region or the remote plasma system may be greater than or about 1 sccm, and may be greater than or about 5 sccm, greater than or about 10 sccm, greater than or about 15 sccm, greater than or about 20 sccm, greater than or about 25 sccm, greater than or about 30 sccm, greater than or about 35 sccm, greater than or about 40 sccm, greater than or about 45 sccm, greater than or about 50 sccm, greater than or about 60 sccm, greater than or about 75 sccm, greater than or about 100, or higher. These flow rates may apply to each of the precursors provided at operation 425 or a total flow rate of all of the precursors provided at operation 425.

In embodiments, the etching may be a thermal or gas-phase only operation. Accordingly, the processing region may be maintained plasma-free while providing the etchant precursor(s) and/or contacting the substrate with the etchant precursor(s) as discussed below. Plasma-free conditions may limit bombardment and may allow only the treated portion of the layer of silicon-containing material to be etched. However, it is contemplated that plasma effluents of the etchant precursor(s) could be formed to increase the etch rate. For example, low level plasma effluents could be formed to increase the etch rate while minimizing bombardment and resultant damage to the substrate or layers disposed thereon.

Method 400 may include contacting the substrate with the etchant precursor(s) at operation 425. By contacting the substrate with the etchant precursor(s), the treated portion of the silicon-containing material may be removed. The treated portion of the silicon-containing material may be selectively removed relative to other materials on the substrate, which may include other silicon-containing materials, such as in a gate all around (GAA) structure. The contacting may continue for a sufficient period of time to etch the treated portion of the silicon-containing material. In embodiments, the period of time may be greater than or about 1 second, and may be greater than or about 2 seconds, greater than or about 3 seconds, greater than or about 4 seconds, greater than or about 5 seconds, greater than or about 6 seconds, greater than or about 7 seconds, greater than or about 8 seconds, greater than or about 9 seconds, greater than or about 10 seconds, greater than or about 15 seconds, greater than or about 20 seconds, greater than or about 30 seconds, greater than or about 1 minute, greater than or about 2 minutes, or more. However, since the treatment may be self-limiting and as the contacting at operation 425 may selectively etch the treated portion of the silicon-containing material, increased periods of time may not etch an increased portion of the silicon-containing material. Accordingly, the period of time may be less than or about 5 minutes, less than or about 4 minutes, less than or about 3 minutes, less than or about 2 minutes, less than or about 1 minute, less than or about 50 seconds, less than or about 40 seconds, less than or about 30 seconds, less than or about 20 seconds, less than or about 10 seconds, or less.

As previously discussed, the treatment and resultant etch may be self-limiting as the treatment precursors may only be able to treat a certain thickness of the silicon-containing material and the etching may only remove the treated portion of the silicon-containing material. In embodiments, the portion of the layer of the silicon-containing material that is removed may be characterized by a thickness of greater than or about 5 Å, and may be characterized by a thickness of greater than or about 5.5 Å, greater than or about 6 Å, greater than or about 6.5 Å, greater than or about 7 Å, greater than or about 7.5 Å, greater than or about 8 Å, greater than or about 8.5 Å, greater than or about 9 Å, greater than or about 9.5 Å, greater than or about 10 Å, or more. Similarly, the portion of the layer of the silicon-containing material that is removed may be characterized by a thickness of less than or about 25 Å, and may be characterized by a thickness of less than or about 20 Å, less than or about 18 Å, less than or about 16 Å, less than or about 14 Å, less than or about 12 Å, less than or about 10 Å, or less.

As illustrated in FIG. 4, the operations of method 400 may be repeated for a second cycle or a plurality of cycles. By repeating the operations, the layer of the silicon-containing material may be iteratively removed on a self-limited basis. In embodiments, operations 405-430 may be repeated for, for example, greater than or about two cycles, and may be repeated for greater than or about three cycles, greater than or about four cycles, greater than or about five cycles, greater than or about ten cycles, greater than or about twenty cycles, greater than or about thirty cycles, or more.

Process conditions may also impact the operations performed in method 400 as well as other methods according to the present technology. Each of the operations of method 400 may be performed during a constant temperature in embodiments, while in some embodiments the temperature may be adjusted during different operations. In embodiments, the treatment at operations 405-415 may be performed at a higher temperature than the etch at operations 425-430. Due to the differences in temperatures, the treatment may be performed in a first semiconductor processing chamber and the etch may be performed in a second semiconductor processing chamber which may or may not be on the same mainframe as the first semiconductor processing chamber. For example, the substrate, pedestal, or chamber temperature while contacting the substrate with the treatment precursor(s) and/or the etchant precursor(s) may be maintained between about 0° C. and about 500° C. in embodiments. The temperature may also be maintained at less than or about 480° C., and may be maintained at less than or about 460° C., less than or about 440° C., less than or about 420° C., less than or about 400° C., less than or about 380° C., less than or about 360° C., less than or about 350° C., less than or about 340° C., less than or about 330° C., less than or about 320° C., less than or about 310° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., less than or about 80° C., less than or about 60° C., less than or about 50° C., less than or about 40° C., or lower. In embodiments, the temperature may also be maintained at greater than or about or about 0° C., and may be maintained at greater than or about or about 10° C., greater than or about or about 20° C., greater than or about or about 30° C., greater than or about or about 40° C., greater than or about or about 50° C., greater than or about or about 60° C., greater than or about or about 80° C., greater than or about or about 100° C., greater than or about or about 120° C., greater than or about or about 140° C., greater than or about or about 160° C., greater than or about or about 180° C., greater than or about or about 200° C., greater than or about or about 220° C., greater than or about or about 240° C., greater than or about or about 260° C., greater than or about or about 280° C., greater than or about or about 300° C., or higher. Temperature may affect the treatment operation and/or etching operation. For example, lower temperatures may increase selectivity during the etch.

The pressure within the chamber may also affect the operations performed. Each of the operations of method 400 may be performed during a constant pressure in embodiments, while in some embodiments the pressure may be adjusted during different operations. In embodiments the pressure within the semiconductor processing chamber may be maintained at less than about 10 Torr, and may be maintained at less than or about 9 Torr, less than or about 8 Torr, less than or about 7 Torr, less than or about 6 Torr, less than or about 5 Torr, less than or about 4.5 Torr, less than or about 4 Torr, less than or about 3.5 Torr, less than or about 3 Torr, less than or about 2.5 Torr, less than or about 2 Torr, less than or about 1.5 Torr, less than or about 1 Torr, or less. Pressure may affect the treatment operation and etching operation. For example, lower pressures may more effectively impact the depth or thickness of the portion of the layer of the silicon-containing material affected by the treatment, with reduced pressures resulting in increased depths or thicknesses. However, lower pressure may result in a reduced etch rate during the etching portion of the method. Conversely, higher pressures may result in a reduced depth or thickness of the portion of the layer of the silicon-containing material affected by the treatment, but may result in a faster etch rate during the etching portion of the method. It is contemplated that the treatment and etching may be performed in different semiconductor processing chambers, which may or may not be on the same cluster tool or mainframe. Accordingly, the pressure may be different between individual semiconductor processing chambers, which may allow for tuning of the treatment depth or thickness and etch rate.

Turning to FIGS. 5A-5D, shown cross-sectional views of structure 500 being processed according to embodiments of the present technology. As illustrated in FIG. 5A substrate 505 may have plurality of stacked layers overlying the substrate, which may be silicon-containing material, silicon-and-germanium-containing material, or other substrate materials. The alternating layers of material may include materials suitable for GAA structures, such as silicon-containing material 510 alternating with silicon-and-germanium-containing material 515. The silicon-and-germanium-containing material 515 may be recessed to produce nanowires/nanosheets in GAA structure. Although illustrated with only five layers of material, exemplary structures may include any of the numbers of layers previously discussed. Additional materials for a GAA structure may be formed over the alternating layers of material. After the silicon-and-germanium-containing material 515 is recessed, a spacer material 520 may be deposited over the structure 500. The spacer material 520 may be an inner spacer of a GAA structure. The spacer material 520 may be a silicon-containing material, such as a silicon-and-oxygen-containing material. The silicon-containing material of the spacer material 520 may further include carbon, nitrogen, or both.

FIG. 5B illustrates structure 500 after some operations of methods according to the present technology have been performed, such as discussed with respect to FIG. 4 above. For example, the substrate 505 may have been contacted with plasma effluents of the treatment precursor(s), such as at operation 415, to form a portion of the layer of the silicon-containing material 525, with reduced carbon concentration, nitrogen concentration, or both.

FIG. 5C illustrates structure 500 after further operations of methods according to the present technology have been performed, such as discussed with respect to FIG. 4 above. An etching operation, such as at operation 430, may be performed to remove the portion of the layer of the silicon-containing material 525. The etching may recess the spacer material 520. As previously discussed, the etching may be self-limiting and multiple iterations of method 400 may be necessary to fully recess the spacer material 520. FIG. 5D illustrates structure 500 after multiple iterations of method 400 have been performed to remove the spacer material 520. However, as illustrated in FIG. 5D, a portion of the spacer material 520 may remain in recesses defined by the silicon-containing material 510 and the silicon-and-germanium-containing material 515, such as where the silicon-and-germanium-containing material 515 was recessed to form an indentation.

The present technology may iteratively remove a silicon-containing material selective to one or more other silicon-containing materials. By first treating the silicon-containing material to be removed with treatment precursor(s) or plasma effluents thereof, carbon and/or nitrogen may be removed. The carbon-deficient and/or nitrogen-deficient silicon-containing material may be selectively removed in a subsequent etching operation. In GAA structures, a reactive ion etching (RIE) may conventionally be performed to remove the inner spacer, such as the silicon-containing material. However, RIE may damage other materials on the substrate, such as shallow trench isolation material. Additionally, RIE may result in carbon and/or nitrogen contamination on other materials of the structure, such as areas that may subsequently have epitaxial material formed thereon. The damage and/or contamination may degrade performance of final devices. The self-limited treatment and etching of the silicon-containing material of the present technology may limit damage to other materials on the substrate as well as reducing contamination. Accordingly, the present technology may result in improved performance, such as electrical performance, of final devices.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a hydrogen-containing precursor and a nitrogen-containing precursor to a processing region of a semiconductor processing chamber, wherein a substrate is disposed within the processing region, and wherein the substrate comprises a layer of a silicon-containing material;
forming plasma effluents of the hydrogen-containing precursor and the nitrogen-containing precursor;
contacting the substrate with plasma effluents of the hydrogen-containing precursor and the nitrogen-containing precursor, wherein the contacting reduces a carbon concentration, a nitrogen concentration, or both in a portion of the layer of the silicon-containing material;
providing one or more etchant precursors to the processing region; and
contacting the substrate with the one or more etchant precursors, wherein the contacting removes the portion of the layer of the silicon-containing material.

2. The semiconductor processing method of claim 1, wherein the hydrogen-containing precursor comprises diatomic hydrogen (H₂).

3. The semiconductor processing method of claim 1, wherein the nitrogen-containing precursor comprises diatomic nitrogen (N₂).

4. The semiconductor processing method of claim 1, wherein the silicon-containing material further comprises carbon, nitrogen, or both.

5. The semiconductor processing method of claim 1, wherein the portion of the layer of the silicon-containing material is characterized by a thickness of greater than or about 5 Å.

6. The semiconductor processing method of claim 1, wherein the portion of the layer of the silicon-containing material is characterized by a thickness of less than or about 25 Å.

7. The semiconductor processing method of claim 1, wherein the processing region is maintained plasma-free while contacting the substrate with the one or more etchant precursors.

8. The semiconductor processing method of claim 1, further comprising:
repeating the operations for a plurality of cycles to remove the layer of the silicon-containing material.

9. The semiconductor processing method of claim 1, wherein a temperature within the processing region is maintained at less than or about 500° C.

10. The semiconductor processing method of claim 1, wherein a pressure within the processing region is maintained between about 1 Torr and about 10 Torr.

11. The semiconductor processing method of claim 1, wherein the layer of the silicon-containing material comprises an inner spacer of a gate all around (GAA) structure.

12. A semiconductor processing method comprising:
treating a layer of a silicon-containing material on a substrate is disposed within a processing region of a semiconductor processing chamber, wherein the treating removes carbon, nitrogen, or both from the layer of the silicon-containing material;
providing one or more etchant precursors to the processing region; and
contacting the substrate with the one or more etchant precursors, wherein the contacting removes a portion of the layer of the silicon-containing material.

13. The semiconductor processing method of claim 12, wherein treating the layer of the silicon-containing material comprises contacting the layer of the silicon-containing material with plasma effluents of a hydrogen-containing precursor and a nitrogen-containing precursor.

14. The semiconductor processing method of claim 13, wherein the plasma effluents of the hydrogen-containing precursor and the nitrogen-containing precursor are formed at a plasma power of greater than or about 1,000 W.

15. The semiconductor processing method of claim 12, wherein the one or more etchant precursors comprise one or more fluorine-containing precursors.

16. The semiconductor processing method of claim 15, wherein the one or more fluorine-containing precursors comprise hydrogen fluoride (HF), nitrogen trifluoride (NF₃), or both.

17. The semiconductor processing method of claim 12, wherein the layer of the silicon-containing material is treated for a period of time greater than or about 5 seconds.

18. The semiconductor processing method of claim 12, wherein:
the substrate further comprises a second silicon-containing material; and
the contacting of the substrate with the one or more etchant precursors selectively removes the portion of the layer of the silicon-containing material relative to the second silicon-containing material.

19. A semiconductor processing method comprising:
providing a hydrogen-containing precursor and a nitrogen-containing precursor to a processing region of a semiconductor processing chamber, wherein a substrate is disposed within the processing region, and wherein the substrate comprises a layer of a silicon-containing material;
forming plasma effluents of the hydrogen-containing precursor and the nitrogen-containing precursor;
contacting the substrate with plasma effluents of the hydrogen-containing precursor and the nitrogen-containing precursor, wherein the contacting reduces a carbon concentration, a nitrogen concentration, or both in a portion of the layer of the silicon-containing material;
halting a flow of the hydrogen-containing precursor and the nitrogen-containing precursor;
providing one or more fluorine-containing precursors to the processing region; and
contacting the substrate with the one or more fluorine-containing precursors, wherein the contacting removes the portion of the layer of the silicon-containing material, and wherein the processing region is maintained plasma-free while contacting the substrate with the one or more fluorine-containing precursors.

20. The semiconductor processing method of claim 19, further comprising:
repeating the operations for a plurality of cycles to remove the layer of the silicon-containing material.
